(19) United States
(12) Patent Application Publication
(10) Pub. No.: US 2016/0223767 A1
(43) Pub. Date: Aug. 4, 2016

(54) OPTICAL FIBER DEVICE

(71) Applicant: USHIO DENKI KABUSHIKI KAISHA, Tokyo (JP)

(72) Inventors: Satoshi MURAKAMI, Himeji-shi (JP); Satoru FUKUDA, Himeji-shi (JP)

(73) Assignee: USHIO DENKI KABUSHIKI KAISHA, Tokyo (JP)

(21) Appl. No.: 14/917,425

(22) PCT Filed: Jul. 24, 2014
(86) PCT No.: PCT/JP2014/069575

§ 371 Date: Mar. 8, 2016

(30) Foreign Application Priority Data
Sep. 11, 2013 (JP) 2013-188179

(51) Int. Cl. G02B 6/42; G02B 6/43; H01S 5/40; G02B 6/32

(52) U.S. Cl. CPC G02B 6/4292; G02B 6/32; G02B 6/4206; G02B 6/43; H01S 5/4012

(57) ABSTRACT

In an optical fiber device (1), a fiber connection unit is provided with a laser light path unit (73) formed into a hollow shape such that a laser light incident on the core (21a) passes through an interior of the laser light path unit, the laser light path unit (73) is provided with a diaphragm unit (73b) formed to have an inner width dimension smaller than an outer width dimension of the core (21a), and a touching portion (73c) formed to have an inner width dimension larger than the outer width dimension of the core (21a) so as to touch a portion outside the core (21a) on an end face on an incident side of the optical fiber unit (2), the touching portion (73c) arranged on an end on a downstream side.

### TECHNICAL FIELD

The present invention relates to an optical fiber device provided with an optical fiber unit including a core which transmits laser light on a central portion thereof.

### BACKGROUND ART

An optical fiber device provided with an optical fiber unit including a core which transmits laser light on a central portion thereof and a laser light path unit formed into a hollow shape such that the laser light incident on the core passes through an interior thereof is conventionally known as the optical fiber device (for example, Patent Document 1). In such optical fiber device, the laser light path unit is provided with a diaphragm unit, so that the laser light which is not incident on the core is blocked by the diaphragm unit.

Position alignment between an incident surface of the optical fiber unit and the diaphragm unit is required for the laser light to be efficiently incident on the core. When the position alignment is not sufficient, for example, the laser light is incident on a clad located outside the core and the clad formed of resin and the like might get burned. There is also a case in which the incident surface of the core is damaged due to contact of the diaphragm unit and the like with the incident surface of the core at the time of the position alignment, for example.

### PRIOR ART DOCUMENT

### Patent Document

Patent Document 1: JP-A-7-92348

### SUMMARY OF THE INVENTION

### Problems to be Solved by the Invention

Therefore, in consideration of such circumstances, an object of the present invention is to provide an optical fiber device in which the laser light may be efficiently incident on the core.

### Means for Solving the Problems

According to the present invention, there is provided an optical fiber device, which includes:
an optical fiber unit including a core which transmits laser light on a central portion; and
a fiber connection unit which connects an end on an incident side of the optical fiber unit, wherein
the fiber connection unit is provided with a laser light path unit formed into a hollow shape such that the laser light incident on the core passes through an interior of the laser light path unit, and
the laser light path unit is provided with a diaphragm unit formed to have an inner width dimension smaller than an outer width dimension of the core, and a touching portion formed to have an inner width dimension larger than the outer width dimension of the core so as to touch a portion outside the core on an end face on the incident side of the optical fiber unit, the touching portion arranged on an end on a downstream side.

According to the optical fiber device according to the present invention, the fiber connection unit connects the end on the incident side of the optical fiber unit and the laser light passes through the interior of the laser light path unit formed into a hollow shape and is incident on the core located on the central portion of the optical fiber unit to be transmitted by the core. The laser light path unit is provided with the diaphragm unit and the inner width dimension of the diaphragm unit is smaller than the outer width dimension of the core, so that it is possible to inhibit the laser light from being incident on the portion outside the core.

Since the touching portion arranged on the end on the downstream side of the laser light path unit is formed to have the inner width dimension larger than the outer width dimension of the core, this touches the portion outside the core on the end face on the incident side of the optical fiber unit. According to this, it is possible to easily position the optical fiber unit relative to the fiber connection unit by allowing the end face on the incident side of the optical fiber unit to touch the touching portion and it is possible to prevent the incident surface of the core from being damaged even when there is the diaphragm unit having the inner width dimension smaller than the outer width dimension of the core. In this manner, the laser light may be efficiently incident on the core.

Also, the optical fiber device according to the present invention may further include:
an optical system which condenses the incident laser light to exit toward the laser light path unit,
the optical fiber device satisfies

W1≧W2+2W3×tan (θ1/2)
when the outer width dimension of the core is W1, the inner width dimension of the diaphragm unit is W2, a clearance between the end face on the incident side of the optical fiber unit and the diaphragm unit is W3, and an angular aperture of the optical system is θ1.

According to such configuration, the optical system condenses the incident laser light at an angular aperture θ1 to exit. The laser light exited from the optical system passes through the diaphragm unit to be incident on the core of the optical fiber unit. At that time, the above-described relational equation is satisfied, so that the laser light which passes through the diaphragm unit is entirely incident on the core of the optical fiber unit. Therefore, the laser light may be further efficiently incident on the core.

Also, the optical fiber device according to the present invention may have a configuration in which:
the optical fiber device satisfies

W1≧W2+2W3×tan (θ2/2)
when the outer width dimension of the core is W1, the inner width dimension of the diaphragm unit is W2, the clearance between the end face on the incident side of the optical fiber unit and the diaphragm unit is W3, and an angle of a vertex of maximum conical laser light incident on the core is θ2.

According to such configuration, when the angle of the vertex of the maximum conical laser light incident on the core is θ2, the laser light incident on the core is condensed by using the optical system having the angular aperture θ2 or smaller in general. The condensed laser light passes through the diaphragm unit to be incident on the core of the optical fiber unit. At that time, the above-described relational equation is satisfied, so that the laser light which passes through the diaphragm unit is entirely incident on the core of the optical fiber unit. Therefore, the laser light may be further efficiently incident on the core.

### Effect of the Invention

As described above, the optical fiber device according to the present invention has an excellent effect that the laser light may be efficiently incident on the core.

### BRIEF DESCRIPTION OF THE DRAWINGS

FIG. 1 is an entire schematic diagram of an optical fiber device according to one embodiment of the present invention.

FIG. 2 is a cross-sectional view of a substantial part of the optical fiber device according to the same embodiment.

FIG. 3 is an enlarged view of a substantial part in FIG. 2 of the optical fiber device according to the same embodiment.

FIG. 4 is a view illustrating a size of the optical fiber device according to the same embodiment.

FIG. 5 is a view illustrating an effect of the optical fiber device according to the same embodiment.

### MODE FOR CARRYING OUT THE INVENTION

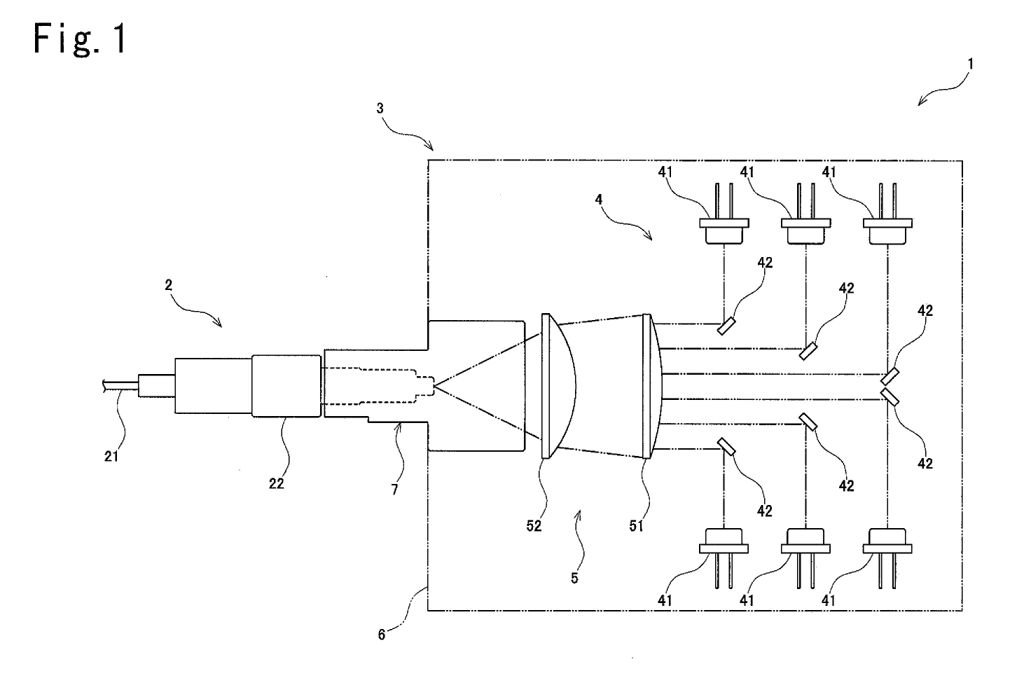

One embodiment of an optical fiber device according to the present invention is hereinafter described with reference to FIGS. 1 to 5.

As illustrated in FIG. 1, an optical fiber device 1 according to this embodiment is provided with an optical fiber unit 2 which transmits laser light. The optical fiber device 1 is also provided with a light source device 3 which exits the laser light toward the optical fiber unit 2.

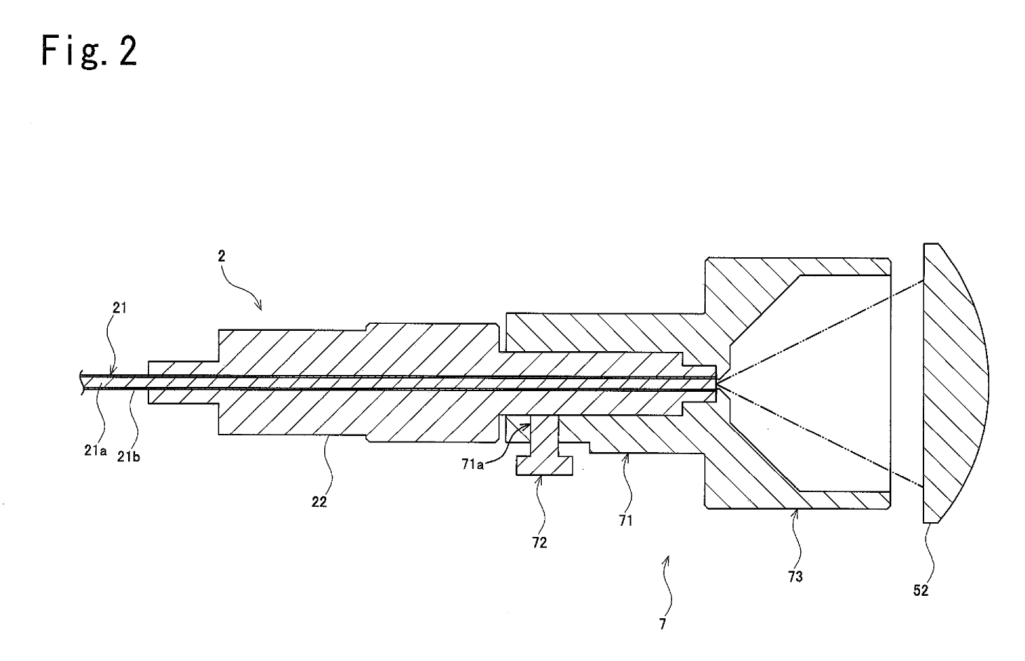

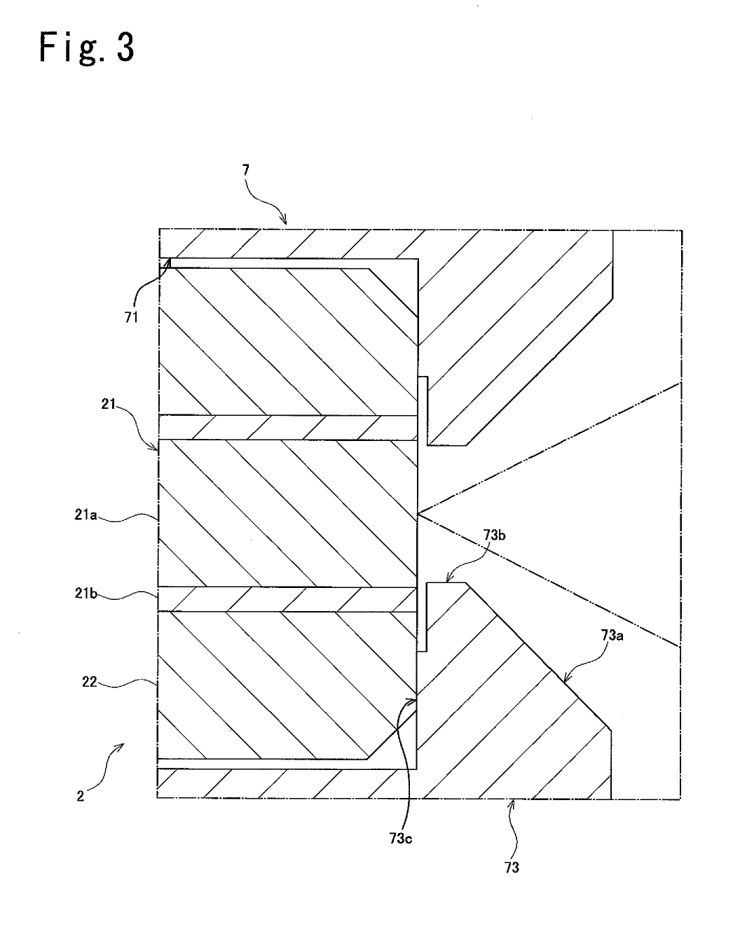

The optical fiber unit 2 is provided with an optical fiber 21 which transmits the laser light and a ferrule 22 in which the optical fiber 21 is arranged so as to be held and fixed as illustrated in FIGS. 2 and 3. The optical fiber 21 is provided with a core 21a arranged on a central portion thereof to transmit the laser light and a clad 21b having a refractive index lower than that of the core 21a arranged outside the core 21a.

The core 21a is formed to have a circular cross-sectional shape, specifically, a perfectly circular cross-sectional shape. The clad 21b is formed outside the core 21a to have a constant thickness dimension. Therefore, the optical fiber 21 is formed to have the circular cross-sectional shape, specifically, the perfectly circular cross-sectional shape. Although the clad 21b is formed of resin in this embodiment, a configuration is not limited thereto and this may also be formed of silica glass, for example.

With reference to FIG. 1 again, the light source device 3 is provided with a light source unit 4 which exits the laser light and an optical system 5 on which the laser light exited from the light source unit 4 is incident. The light source device 3 is also provided with a housing 6 which accommodates the light source unit 4 and the optical system 5 and a fiber connection unit 7 fixed to the housing 6 to connect the optical fiber unit 2.

The light source unit 4 is provided with a plurality of semiconductor lasers 41 which generates the laser light to exit. The light source unit 4 is also provided with a plurality of reflecting mirrors 42 which reflects the laser light exited from each semiconductor laser 41 toward the optical system 5. The light source unit 4 is configured such that light axes of the light exited from a plurality of semiconductor lasers 41 are parallel to one another when incident on the optical system 5. Meanwhile, although six semiconductor lasers 41 and six reflecting mirrors 42 are provided in FIG. 1, the numbers are not limited thereto.

The optical system 5 is provided with a pair of lenses 51 and 52 which condenses the incident laser light to exit. The optical system 5 condenses the incident laser light to exit toward the fiber connection unit 7 and the optical fiber unit 2. Meanwhile, although the optical system 5 is provided with two lenses 51 and 52 in this embodiment, the number is not limited thereto.

The first lens 51 on which the laser light exited from the light source unit 4 is incident condenses the incident laser light to exit toward the second lens 52. The second lens 52 on which the laser light exited from the first lens 51 is incident condenses the incident laser light to exit toward the fiber connection unit 7 and the optical fiber unit 2.

The fiber connection unit 7 is provided with a tubular fiber insertion unit 71 into which an end on an incident side of the optical fiber unit 2 is inserted and a fixing mechanism 72 for fixing the optical fiber unit 2 to the fiber insertion unit 71 so as to detachably connect the optical fiber unit 2 as illustrated in FIGS. 2 and 3. The fiber connection unit 7 is also provided with a laser light path unit 73 formed into a hollow shape such that the laser light incident on the core 21a of the optical fiber unit 2 passes through an interior thereof. The fiber insertion unit 71 and the laser light path unit 73 are in communication with each other and the fiber connection unit 7 is formed into a tubular shape as a whole.

The fixing mechanism 72 is a screw member 72 screwed with a screw hole 71a provided on the fiber insertion unit 71 in this embodiment. The screw member 72 presses the optical fiber unit 2, thereby attaching the optical fiber unit 2 to the fiber connection unit 7, and in contrast, the screw member 72 releases pressure on the optical fiber unit 2, thereby detaching the optical fiber unit 2 from the fiber connection unit 7.

The laser light path unit 73 is provided with a light path unit main body 73a having an inner aperture formed to be gradually smaller from an upstream side toward a downstream side and a diaphragm unit 73b formed to have a smallest inner width dimension arranged downstream from the light path unit main body 73a. The laser light path unit 73 is also provided with a touching portion 73c touching an end face on the incident side of the optical fiber unit 2 on an end on the downstream side thereof.

The inner width dimension (inner diameter) of the diaphragm unit 73b is smaller than an outer width dimension (outer diameter) of the core 21a. According to this, the laser light which passes through the diaphragm. unit 73b is inhibited from being incident on a portion outside the core 21a, that is to say, the clad 21b and the ferrule 22.

An inner width dimension (inner diameter) of the touching portion 73c is larger than the outer width dimension (outer diameter) of the core 21a. According to this, the touching portion 73c touches the portion outside the core 21a on the end face on the incident side of the optical fiber unit 2, that is to say, the clad 21b and the ferrule 22 (only the ferrule 22 in this embodiment).

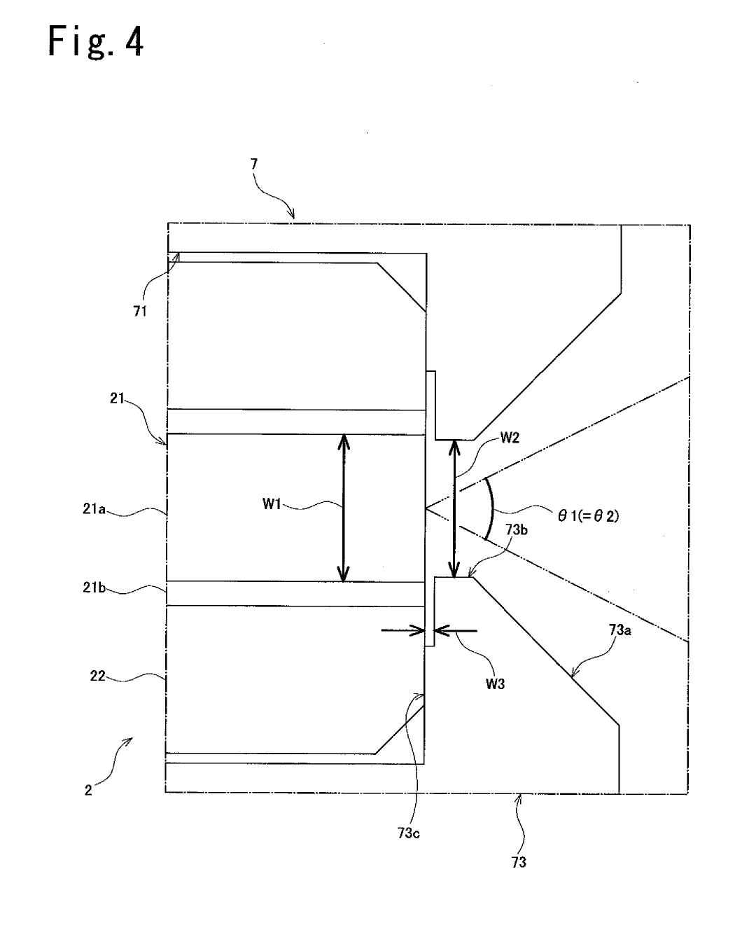

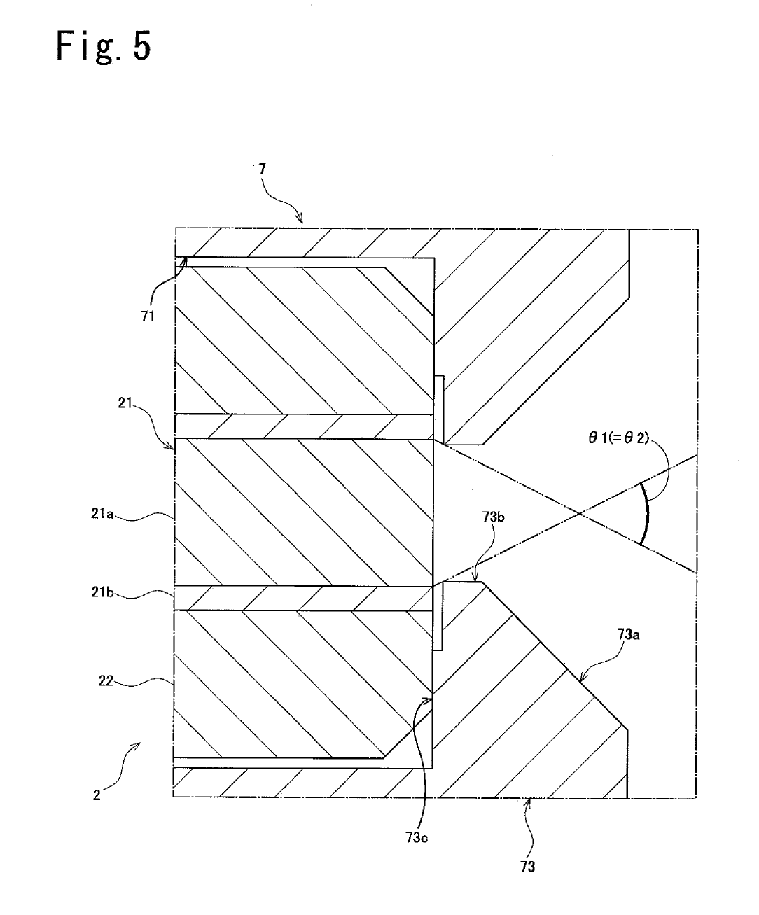

A size of each configuration of the optical fiber device 1 according to this embodiment and an effect thereby are herein described with reference to FIGS. 4 and 5.

A relationship among an outer width dimension (outer diameter) W1 of the core 21a, an inner width dimension (inner diameter) W2 of the diaphragm unit 73b, a clearance W3 between the incident side end face of the fiber unit 7 and the diaphragm unit 73b, and an angular aperture θ1 of the optical system 5 is first described as illustrated in FIG. 4. In this embodiment, the angular aperture θ1 of the optical system 5 (a visual angle of a diameter of an incident pupil as seen from an object point on a light axis) is an angle at which the lens (second lens) 52 arranged on a most downstream side of the optical system 5 condenses the laser light.
They are set to satisfy following equation 1.

W1≧W2+2W3×tan (θ1/2) (Equation 1)

A relationship among the outer width dimension W1 of the core 21a, the inner width dimension W2 of the diaphragm unit 73b, the clearance W3 between the incident side end face of the fiber unit 7 and the diaphragm unit 73b, and an angle θ2 of a vertex of maximum conical laser light incident on the core 21a is next described. In general, the angular aperture θ1 of the optical system 5 is set to be the angle θ2 or smaller such that the laser light exited from the optical system 5 is maximally incident on the core 21a. Meanwhile, in this embodiment, the angle θ2 and the angular aperture θ1 of the optical system 5 are set to be identical to each other.

They are set to satisfy following equation 2.

W1≧W2+2W3×tan (θ2/2) (Equation 2)

Since equations 1 and 2 described above are satisfied, as illustrated in FIG. 5, the laser light which passes through the diaphragm unit 73b is surely incident on the core 21a even when this is spread at the angle θ1 (=θ2) and is not incident on the clad 21b and the ferrule 22 which are the portions outside the core 21a. Meanwhile, the center of the core 21a, the center of the laser light path unit 73, and the light axis of the laser light exited from the optical system 5 are located on the same straight line.

From above, according to the optical fiber device 1 according to this embodiment, the fiber connection unit 7 connects the incident side end of the optical fiber unit 2 and the laser light passes through the interior of the laser light path unit 73 formed into a hollow shape and is incident on the core 21a located on the central portion of the optical fiber unit 2 to be transmitted by the core 21a.

The diaphragm unit 73b is provided on the laser light path unit 73 and the inner width dimension of the diaphragm unit 73b is smaller than the outer width dimension of the core 21a, so that it is possible to inhibit the laser light from being incident on the portion outside the core 21a. Therefore, it is possible to prevent the clad 21b formed of resin from getting burned by the laser light.

Furthermore, the touching portion 73c arranged on the end on the downstream side of the laser light path unit 73 is formed to have the inner width dimension larger than the outer width dimension of the core 21a, so that this touches the portion outside the core 21a on the incident side end face of the optical fiber unit 2. According to this, it is possible to easily position the optical fiber unit 2 relative to the fiber connection unit 7 by allowing the incident side end face of the optical fiber unit 2 to touch the touching portion 73c and it is possible to prevent an incident surface of the core 21a from being damaged even when there is the diaphragm unit 73b having the inner width dimension smaller than the outer width dimension of the core 21a. In this manner, the laser light may be efficiently incident on the core 21a.

According to the optical fiber device 1 according to this embodiment, the optical system 5 condenses the incident laser light to exit. The laser light exited from the optical system 5 passes through the diaphragm unit 73b to be incident on the core 21a of the optical fiber unit 2. At that time, equation 1 described above is satisfied, so that the laser light which passes through the diaphragm unit 73b is entirely incident on the core 21a of the optical fiber unit 2. Therefore, the laser light may be further efficiently incident on the core 21a.

According to the optical fiber device 1 according to this embodiment, the angle of the vertex of the maximum conical laser light incident on the core 21a is θ2 and the laser light incident on the core 21a is condensed by using the optical system 5 having the angular aperture θ1 which is the same as θ2. The condensed laser light passes through the diaphragm unit 73b to be incident on the core 21a of the optical fiber unit 2. At that time, equation 2 described above is satisfied, so that the laser light which passes through the diaphragm unit 73b is entirely incident on the core 21a of the optical fiber unit 2. Therefore, the laser light may be further efficiently incident on the core 21a.

Meanwhile, the optical fiber device according to the present invention is not limited to the configuration of the above-described embodiment or to the above-described effect. It goes without saying that the optical fiber device according to the present invention may be variously modified without departing from the gist of the present invention. For example, it goes without saying that a configuration and a method according to various variations to be described below may be arbitrarily selected to be adopted to the configuration and the method according to the above-described embodiment.

In the optical fiber device 1 according to the above-described embodiment, the optical fiber 21 and the core 21a are configured to be formed to have the perfectly circular cross-sectional shapes. However, the optical fiber device according to the present invention is not limited to such configuration. For example, in the optical fiber device according to the present invention, the optical fiber 21 and the core 21a may be configured to be formed to have elliptical or polygonal cross-sectional shapes.

In the optical fiber device 1 according to the above-described embodiment, the optical fiber unit 2 is configured to be provided with the optical fiber 21 and the ferrule 22 in which the optical fiber 21 is arranged to be held and fixed. However, the optical fiber device according to the present invention is not limited to such configuration.

For example, in the optical fiber device according to the present invention, the optical fiber unit 2 may be configured to be formed of the optical fiber. In such optical fiber, for example, an optical fiber strand provided with primary coating outside a clad of a bare optical fiber formed of a core and the clad may be adopted or an jacketed optical fiber further provided with secondary coating outside the optical fiber strand may be adopted.

In the optical fiber device 1 according to the above-described embodiment, it is configured such that the angular aperture θ1 of the optical system 5 and the angle θ2 of the vertex of the maximum conical laser light incident on the core 21a are set to be identical to each other. However, the optical fiber device according to the present invention is not limited to such configuration. For example, in the optical fiber device according to the present invention, it may be configured such that the angular aperture θ1 of the optical system 5 is set to be different from the angle θ2 of the vertex of the maximum conical laser light incident on the core 21a.

### DESCRIPTION OF REFERENCE SIGNS

1 optical fiber device
2 optical fiber unit
3 light source device
4 light source unit
5 optical system
6 housing
7 fiber connection unit
21 optical fiber
21a core
21b clad
22 ferrule
41 semiconductor laser
42 reflecting mirror
51 (first) lens
52 (second) lens
71 fiber insertion unit
71a screw hole
72 fixing mechanism (screw member)
73 laser light path unit
73a light path unit main body
73b diaphragm unit
73c touching portion
W1 outer width dimension of core
W2 inner width dimension of diaphragm unit
W3 distance between incident side end face of fiber unit and diaphragm unit
θ1 angular aperture of optical system
θ2 angle of vertex of maximum conical laser light incident on core

1. An optical fiber device, comprising:
an optical fiber unit including a core which transmits laser light on a central portion; and
a fiber connection unit which connects an end on an incident side of the optical fiber unit, wherein
the fiber connection unit is provided with a laser light path unit formed into a hollow shape such that the laser light incident on the core passes through an interior of the laser light path unit,
the laser light path unit is provided with a diaphragm unit formed to have an inner width dimension smaller than an outer width dimension of the core, and a touching portion formed to have an inner width dimension larger than the outer width dimension of the core so as to touch a portion outside the core on an end face on the incident side of the optical fiber unit, the touching portion arranged on an end on a downstream side,
the optical fiber device further comprises an optical system which condenses the incident laser light to exit toward the laser light path unit, and
the optical fiber device satisfies
W1≧W2+2W3×tan (θ1/2)
when the outer width dimension of the core is W1, the inner width dimension of the diaphragm unit is W2, a clearance between the end face on the incident side of the optical fiber unit and the diaphragm unit is W3, and an angular aperture of the optical system is θ1.

2. (canceled)

3. An optical fiber device comprising:
an optical fiber unit including a core which transmits laser light on a central portion; and
a fiber connection unit which connects an end on an incident side of the optical fiber unit, wherein
the fiber connection unit is provided with a laser light path unit formed into a hollow shape such that the laser light incident on the core passes through an interior of the laser light path unit,
the laser light path unit is provided with a diaphragm unit formed to have an inner width dimension smaller than an outer width dimension of the core, and a touching portion formed to have an inner width dimension larger than the outer width dimension of the core so as to touch a portion outside the core on an end face on the incident side of the optical fiber unit, the touching portion arranged on an end on a downstream side, and
the optical fiber device satisfies
W1≧W2+2W3×tan (θ2/2)
when the outer width dimension of the core is W1, the inner width dimension of the diaphragm unit is W2, a clearance between the end face on the incident side of the optical fiber unit and the diaphragm unit is W3, and an angle of a vertex of maximum conical laser light incident on the core is θ2.
